(19) United States
(12) Patent Application Publication
(10) Pub. No.: US 2016/0211652 A1
(43) Pub. Date: Jul. 21, 2016

(54) LIGHT-SOURCE DEVICE,IN PARTICULAR FOR USE IN A MICROMIRROR DEVICE

(71) Applicant: ROBERT BOSCH GMBH, Stuttgart (DE)

(72) Inventors: Frank Fischer, Gomaringen (DE); Lutz Rauscher, Reutlingen (DE); Gael Pilard, Wankheim (DE)

(21) Appl. No.: 14/912,879

(22) PCT Filed: Jul. 10, 2014
(86) PCT No.: PCT/EP2014/064792

§ 371 Date: Feb. 18, 2016

(30) Foreign Application Priority Data
Aug. 26, 2013 (DE) 10 2013 216 896.9

(51) Int. Cl. H01S 5/40; G02B 27/10; G02B 27/14; G02B 27/48

(52) U.S. Cl. CPC H01S 5/4012; G02B 27/48; G02B 27/1006; G02B 27/14

(57) ABSTRACT

A light source device, in particular for use in a micromirror device, having a first red light source for the emission of light from the red spectral range, a second red light source for the emission of light from the red spectral range, a green light source for the emission of light from the green spectral range, and a blue light source for the emission of light from the blue spectral range, and having superposition element, the superposition element being configured such that the light from the first red light source, the light from the second red light source, the light from the blue light source, and the light from the green light source are superposed in collinear fashion to form a common light beam, the light from the first red light source having a wavelength different from that of the light from the second red light source.

### BACKGROUND INFORMATION

The present invention relates to a light-source.

Such light source devices are generally referred to as RGB modules. The development of powerful and ever-smaller laser light sources has permitted such light source devices to become an essential component of micromirror devices or micromirror actuators, because they are capable of producing bright colored image points despite their small spatial extension. In doing so, they use only the light that is actually consumed. Such micromirror devices can for example in the future form the central component of pico projectors, mini-barcode scanners, or devices for endoscopy. However, the use of laser light turns out to be disadvantageous in that the high coherence of the laser light causes a speckling effect due to interferences on a screen onto which the light is directed. The use of semiconductor lasers having low coherence, and their operation with a modulation of a few 100 MHz, has in the past succeeded in reducing the speckling effect. However, generally, the line width of the red light source is so narrow that, for a significant line widening (and thus for the reduction of the coherence), modulation frequencies are required that are very much higher than those that can be used for the two other light sources. For possible areas of application of the micromirror device or of the micromirror actuator such as projectors, mobile telephones, cameras, or laptops, modulation frequencies greater than 1 GHz are however no longer practicable or desirable. Therefore, the existing art proposes the use of two red light sources that emit light from the red spectral range having polarizations that stand perpendicular to one another. If the two beam paths are superposed with the two polarizations oriented perpendicular to one another, the speckling effect can be reduced by a factor of 1.41. However, there is the disadvantage that for the superposition of the two beam paths a polarization beam divider is required that, in some circumstances, has a destruction threshold that limits the light strength, i.e., the intensity of the light, from the red spectral range. Moreover, it is to be noted that generally the laser light from laser diodes has an asymmetrical beam profile. If the semiconductor laser light is superposed with polarizations perpendicular to one another, the two semi-major axes of the elliptical beam profile, or beam cross-section, then also run perpendicular to one another, which causes the beam width of the common beam (made up of the superposition of the light from the various light sources) to be enlarged overall. Consequently, the resolution capacity is disadvantageously reduced.

An object of example embodiments of the present invention is to realize a low-cost and simple light source device whose resolution capacity is improved by the further reduction of the speckling effect for the light from the red spectral range, while reducing or eliminating the above-named disadvantageous effects present in the existing art.

### SUMMARY

In accordance with the present invention, a light source device is provided, in particular for use in a micromirror device, having a first red light source for emitting light from the red spectral range and having a second red light source for emitting light from the red spectral range. In order to form a common light beam that produces a colored point on the screen, the light source device additionally has a green light source for emitting light from the green spectral range and a blue light source for emitting light from the blue spectral range. Using superposition means, and in particular via the configuration thereof, it is provided that the light from the first red light source, the light from the second red light source, the light from the green light source, and the light from the blue light source are superposed in collinear fashion to form a common light beam. In particular, according to an example embodiment of the present invention it is provided that the light from the first red light source has a different wavelength than does the light from the second red light source.

In particular, in accordance with an example embodiment, it is provided that the wavelength of the light from the first red light source differs from the wavelength of the light from the second red light source by more than 8 nm, preferably by more than 15 nm, and particularly preferably by more than 20 nm.

Compared to the existing art, the example light source device according to the present invention may have the advantage of reducing the speckling effect caused by light from the red spectral range. High modulation frequencies (in the GHz range) for line width expansion can be done without. Modulation frequencies below the GHz range are desirable for example in potential areas of use of the light source device such as projectors, mobile telephones, cameras, or laptops. Because a parallel polarization of the light by a multiplicity of optical elements, for example due to their anti-reflective coating, is preferred, the fact that the light is not superposed with different polarizations is a further advantage. This advantage plays a role in particular when the optical elements used in the particular area of use already have a plurality of coatings, in particular anti-reflective coatings. (Standardly, the anti-reflective coatings have to be already adapted to the wavelength ranges, which is expensive, without losing the effect of the anti-reflective coating, even if the light beam does not impinge on the antireflective coating at precisely the intended angle. The addition of a further condition for the anti-reflective layer can generally be realized only with an inordinately large outlay, entailing additional costs.)

In a further specific embodiment, it is provided that the first red light source, the second red light source, the green light source, and/or the blue light source are semiconductor lasers. Because, generally, semiconductor lasers can be realized with small dimensions, the use of semiconductor lasers as light source confers the advantage that the light source device as a whole can be made with small dimensions. In addition, semiconductor lasers that emit red light are obtainable whose emission wavelengths differ from one another by more than 15 nm, whereby the speckling effect can be reduced particularly strongly, because the reduction of the speckling effect becomes greater the greater the difference in wavelengths is between the superposed light waves.

In a further specific embodiment, it is provided that a superposition element is configured such that the direction of propagation of the light of the second red light source runs collinear with the direction of propagation of the common light beam. In this way, a light source device can be realized in which a deflecting means, such as a mirror, or an additional superposition means can advantageously be omitted that would otherwise be responsible for orienting the direction of propagation of the light of the first red light source, of the second red light source, of the green light source, or of the blue light source collinear to the direction of propagation of the common light beam.

In a further specific embodiment of the present invention, it is provided that at least one superposition element (11, 12, 13) is a wavelength-selective mirror. For example, the wavelength-selective mirror is a dielectric or dichroic mirror. The use of wavelength-selective mirrors confers the advantage that light can be coupled into the common beam without significantly altering the properties of the common beam.

In a further specific embodiment of the present invention, it is provided that all the superposition elements (11, 12, 13) are wavelength-selective mirrors. In this specific embodiment, the use of a polarization beam divider is advantageously eliminated, which as a rule has a destruction threshold that limits the light strength, or intensity of the light source, for the light source device.

In a further specific embodiment of the present invention, it is provided that the light from the first red light source, from the second red light source, from the blue light source, and/or from the green light source is pulsed. The broad line width of pulsed light sources advantageously additionally reduces the coherence, and thus also additionally reduces the speckling effect.

In a further specific embodiment of the present invention, it is provided that the light source device has at least one element for beam formation. For example, a lens can be situated directly behind the first red light source, the second red light source, the green light source, and/or the blue light source that at least partly compensates a possible divergence of the light exiting from the light source. Semiconductor lasers in particular have generally a strong divergence, and their divergence in addition typically causes an asymmetrical beam profile. It is therefore also possible to use cylinder lenses in a preferred specific embodiment. With the aid of the elements for beam formation, it is advantageously possible through partial compensation of the divergence to improve the resolution capacity, compared to the same light source device without beam formation elements.

A further subject matter of the present invention is a micromirror device having at least one light source device according to one of the above-described specific embodiments. Such a micromirror device can make use of the positive properties of the light source device for scanning an image, for example a barcode. Here, the micromirror device has one or more mirrors that orient the common beam, or project it onto the screen.

A further subject matter of the present invention is a projector having at least one light source device according to one of the above-described specific embodiments. Such a projector can use the resolution capacity of the light source device, which is higher due to the reduction of the speckling effect, for improved image representation.

Further details, features, and advantages of the present invention are shown in the figures, and are described below in terms of preferred specific embodiments based on the figures. The figures illustrate specific embodiments of the present invention that are presented only as examples, and which do not limit the essential ideas of the present invention.

### BRIEF DESCRIPTION OF THE DRAWINGS

FIG. 1 shows a light source device according to the existing art.

FIG. 2 shows the beam profile of laser light on a display screen.

FIG. 3 shows a specific embodiment of a light source device according to the present invention.

### DETAILED DESCRIPTION OF EXAMPLE EMBODIMENTS

In the various Figures, identical parts are provided with the same reference characters, and are therefore each only named or mentioned once.

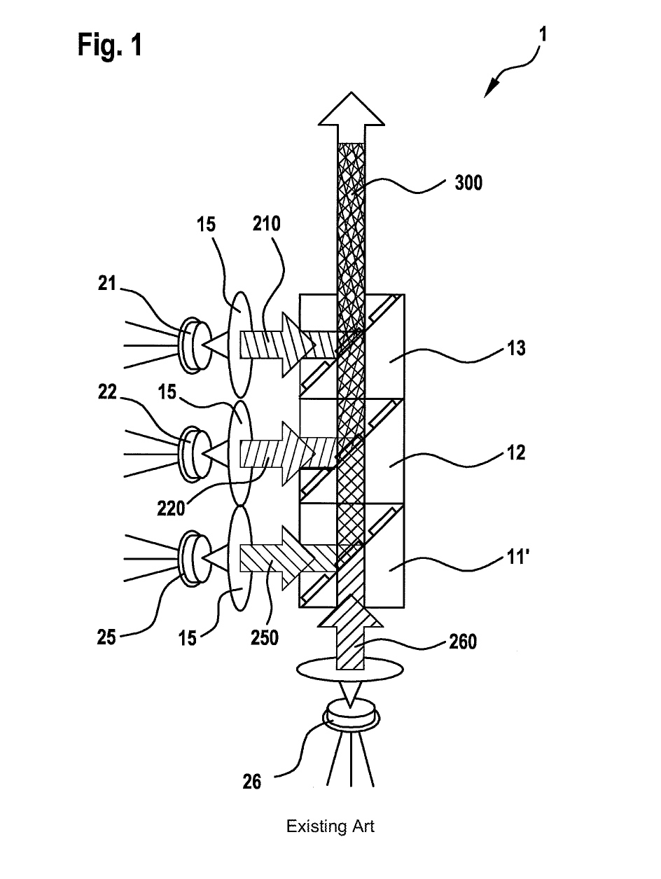

FIG. 1 shows a light source device 1 according to the existing art, made up of a blue light source 22, a green light source 21, and two red light sources 25 and 26, the blue light source emitting light from the blue spectral range 220, the green light source emitting light from the green spectral range 210, and the two red light sources emitting light from the red spectral range 250 and 260. Standardly, for a light source device 1 that is to be situated in a micromirror device it is provided that light from the red, from the green, and from the blue light source 21, 22, and 25 is superposed in such a way that, superposed on a screen, they produce a point having a particular color impression, the desired color impression of the point being determined by the relative mix ratio (or by the relative weighting) of light from the red, green, and blue spectral range 210, 220, and 250. Here, it is possible that the color impression should change at short time intervals if for example light source device 1 is integrated in a projector provided for projecting films. Preferably, the light sources used are lasers. The use of coherent laser light has the disadvantage of the formation of speckling patterns, or of the speckling effect (i.e., interference phenomena on the screen), limiting the resolution capacity of the projector. In particular, the red light source can be manipulated only with difficulty in order to reduce the speckling effect caused by the light emitted by red light source 25. In order to reduce the speckling effect caused by light from the red spectral range, the existing art provides two red light sources 25 and 26, which emit light having the same wavelength from the red spectral range and which differ in that their polarizations are oriented perpendicular to one another. Using a polarization beam divider 11′, the light from the first red light source having a first polarization 250 and the light from a second red light source having a second polarization 260 can be superposed in such a way that the two red beam paths run in a collinear fashion and thus form a common beam 300 that has both the light from the first red light source and also the light from the second red light source. Through the superposition, the coherence of the laser light is reduced and the speckling effect is reduced by a factor of 1.414. Using a second and a third superposition elements 12 and 13, the light from the blue and from the green light source 210 and 220 is supplied to common beam 300 in such a way that common beam 300 includes, in the direction of propagation at the output of light source device 1, the beam paths of the light from red spectral range 250 and 260, from blue spectral range 220, and from green spectral range 210. Second and third superposition elements 12 and 13 are preferably wave-selective mirrors, in particular dielectric mirrors, each fashioned in such a way that they reflect light from a particular spectral range while transmitting light from other spectral ranges or have other wavelengths. For example, second superposition element 12 transmits light from red spectral range 250 and 260, but reflects light 220 exiting from the blue light source. Using dielectric mirrors, the different beams can be superposed in collinear fashion to form a common beam 300 in a simple and space-saving manner. For further miniaturization of such an RGB module, semiconductor lasers are standardly used as light sources. Lenses 15, situated behind the semiconductor laser shown in the Figure, attempt to partially compensate the comparatively high divergence of the light produced by semiconductor lasers (compared to other laser types). In order to bundle as much light as possible to form a light beam, it is provided that lenses 15 are situated as close as possible to the output of the laser light source; i.e., lenses 15 that are used have as a rule a small focal width. A disadvantage of the device according to the existing art is that for superpositions of the two red beam paths a polarization beam divider 11′ is required. The use of such a polarization beam divider 11′ is generally subject to the condition that the light has an intensity that is below a destruction threshold for polarization beam divider 11′. In this way, the intensity that is used for the light from red light source 250 or 260 is disadvantageously limited by the destruction threshold.

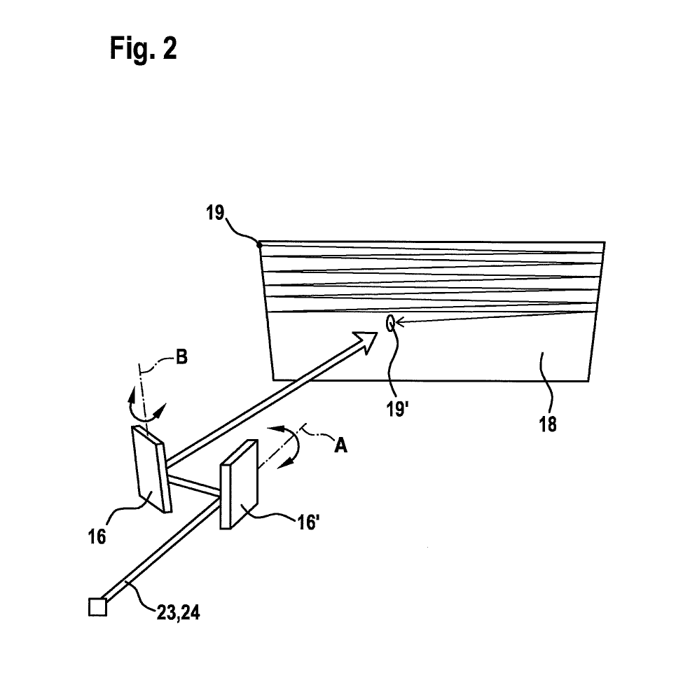

FIG. 2 shows beam profile 19, 19′ of polarized laser light 23, 24 on a screen 18, the laser light being directed onto screen 18 via two mirrors 16, 16′. The two mirrors 16 and 16′ are capable of being pivoted about two axes A and B that are oriented perpendicular to one another. In this way, the spot, or beam profile, 19, 19′ of the laser light can be positioned on the screen. In particular, this light point (i.e., spot, or the beam profile) 19, 19′ can be moved on screen 18. Using the two mirrors 16 and 16′, light point 19, 19′ can scan or search the entire screen 18. It is for example possible that a barcode be attached on screen 18 that is examined or read by light point 19, 19′ via the scanning. It can be seen that beam profile 19, 19′ of the laser light is elliptical, the size of the semi-axis also being a function of the positioning of the light point on screen 18. In some circumstances, the size of the semi-major axis matches the size of the semi-minor axis, and the beam profile is circular. The elliptical beam profile is typical of laser light from semiconductor lasers, which are preferably used in light source device 1. The elliptical beam profile here has a disadvantageous effect on the resolution capacity, and causes a distorted image reproduction.

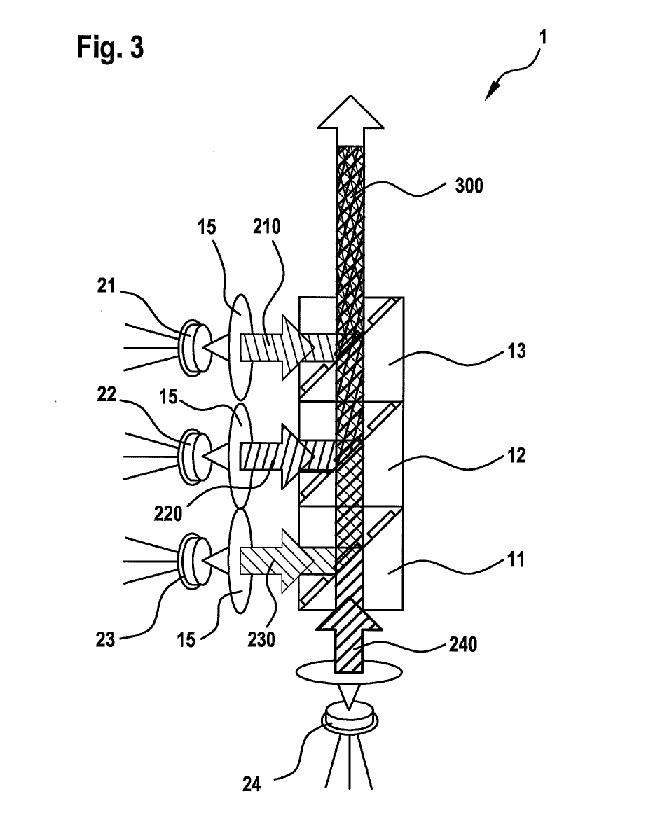

FIG. 3 shows a specific embodiment of a light source device 1 according to the present invention, made up of a blue light source 22, a green light source 21, and two red light sources 23 and 24. As in the light source device of FIG. 1, the light source device 1 according to the present invention also has superposition elements 11, 12, and 13 that superpose, in collinear fashion, the light from the two red light sources 230 and 240, the light from blue light source 220, and the light from green light source 210, to form a common beam 300. Light source device 1 according to the present invention differs from the existing art in that first red light source 23 emits light having a first wavelength from the red spectral range and second red light source 24 emits light having a second wavelength from the red spectral range, the first wavelength differing from the second wavelength. As a function of the difference in wavelengths between the first and the second wavelength, the speckling effect can be reduced. Advantageously, a polarization beam divider 11′ can then be omitted, and instead a dielectric mirror can be used as first superposition element 11. Because, generally, these dielectric mirrors have a very high destruction threshold, depicted light source device 1 makes use of the possibility of using powerful red light sources 23 and 24. Because it is additionally not required to superpose light with polarizations 250 and 260 perpendicular to one another, a light source device 1 according to the present invention also reduces the risk that beam profile 19 enlarges the common beam, thus reducing the resolution capacity. The fact that light having different polarizations is not used has in addition the advantage that coatings, such as anti-reflective coatings, have to be adapted only for one polarization direction of the light. In this way, additional costs and outlay are advantageously avoided in the production of optical elements that are used together with light source device 1 according to the present invention.

1-9. (canceled)

10. A light source device for use in a micromirror device, comprising:
a first red light source for emission of light from a red spectral range, the light having a first wavelength;
a second red light source for emission of light from the red spectral range, the light having a second wavelength that is different than the first wavelength;
a green light source for emission of light from a green spectral range; and
a blue light source for emission of light from a blue spectral range; and
at least one superposition element configured to superpose the light from the first red light source, the light from the second red light source, the light from the green light source, and the light from the blue light source in collinear fashion to form a common light beam.

11. The light source device as recited in claim 10, wherein at least one of the first red light source, the second red light source, the blue light source, and the green light source are semiconductor lasers.

12. The light source device as recited in claim 10, wherein the superposition element is configured in such a way that a direction of propagation of the light from one of the first red light source, of the second red light source, the green light source, or the blue light source, runs collinear to a direction of propagation of the common light beam.

13. The light source device as recited in claim 10, wherein the at least one superposition element is a wavelength-selective mirror.

14. The light source device as recited in claim 10, wherein all superposition elements are wavelength-selective mirrors.

15. The light source device as recited in claim 10, wherein at least one of the light from the first red light source, the second red light source, the blue light source, and the green light source, is pulsed.

16. The light source device as recited in claim 10, wherein the light source device has at least one element for beam formation.

17. A micromirror device, comprising:
at least one light source device including a first red light source for emission of light from a red spectral range, the light having a first wavelength;
a second red light source for emission of light from the red spectral range, the light having a second wavelength that is different than the first wavelength;
a green light source for emission of light from a green spectral range; and
a blue light source for emission of light from a blue spectral range; and
at least one superposition element configured to superpose the light from the first red light source, the light from the second red light source, the light from the green light source, and the light from the blue light source in collinear fashion to form a common light beam.

18. A projector, comprising:
at least one light source device including a first red light source for emission of light from a red spectral range, the light having a first wavelength;
a second red light source for emission of light from the red spectral range, the light having a second wavelength that is different than the first wavelength;
a green light source for emission of light from a green spectral range; and
a blue light source for emission of light from a blue spectral range; and
at least one superposition element configured to superpose the light from the first red light source, the light from the second red light source, the light from the green light source, and the light from the blue light source in collinear fashion to form a common light beam.
